(19) United States
(12) Patent Application Publication
(10) Pub. No.: US 2021/0222286 A1
(43) Pub. Date: Jul. 22, 2021

(54) INSULATION BOARD AND VACUUM EVAPORATION DEVICE ASSEMBLY

(71) Applicant: BEIJING APOLLO DING RONG SOLAR TECHNOLOGY CO., LTD., BEIJING (CN)

(72) Inventor: Weicheng BAO, Beijing (CN)

(73) Assignee: BEIJING APOLLO DING RONG SOLAR TECHNOLOGY CO., LTD., BEIJING (CN)

(21) Appl. No.: 16/096,026

(22) PCT Filed: Jun. 6, 2018
(86) PCT No.: PCT/CN2018/090154

§ 371 Date: Oct. 24, 2018

(30) Foreign Application Priority Data
Jan. 16, 2018 (CN) 201820069061.7

(51) Int. Cl. C23C 14/24; H01L 31/042; C23C 14/54

(52) U.S. Cl. CPC C23C 14/24; C23C 14/541; H01L 31/042

(57) ABSTRACT

An insulation board includes a body; first bulges, disposed on the body and extending toward a first direction; and second bulges, disposed on the body and extending toward a second direction, and the first bulges and the second bulges are staggered, and the first direction is opposed to the second direction.

### TECHNICAL FIELD

The present disclosure relates to the field of technologies of solar cells preparation, and for example, relates to an insulation board and a vacuum evaporation device assembly.

### BACKGROUND

With increasing decrease of petroleum, coal and other natural resources on the earth, development of a new natural resource becomes an urgent matter, and solar energy becomes a focus of development due to an advantage of cleanness.

The utilization of the solar energy mainly refers to transforming solar radiation into electric energy, thermal energy and other resources that humans may use through a solar cell. An efficient hetero junction solar panel becomes a focus of development due to an advantage of efficiency. When a hetero-junction solar panel is prepared, solar cells should be firstly prepared, which are completed by processing in a way of depositing films on surfaces of both sides of a substrate, and when the films are deposited on the surfaces of both sides of the substrate, a vacuum evaporation device will be used.

A process chamber is arranged on the vacuum evaporation device; an evaporation source is arranged in the process chamber; and the substrate is mostly placed at a side face to the evaporation source. When processing, high-temperature sputtered atoms provided by the evaporation source are deposited on the substrate to form the films in a vacuum state.

The above processing needs to be conducted in a high-vacuum and high-temperature environment. Therefore, requirements for insulation and leakproofness of the process chamber are relatively strict. However, an inner wall of a vacuum chamber is generally made of stainless steel (such as stainless steel with a model of X5CrNi18), and such material easily reacts with a process raw material for processing the solar cell when reaching a high temperature above 680K, thereby corroding the inner wall of the process chamber and reducing the service life of the vacuum expiration device; and meanwhile, a high temperature of an internal surface of the process chamber will damage other components, and is also adverse to safety of the device. Therefore, it is urgent to perform insulating protection to the internal surface of the process chamber.

A layer of insulation board is arranged on the inner wall of the process chamber, and made of sandblasted stainless steel. However, in an actual application process, it is found that an insulation effect of the insulation board is not ideal, and in addition, the service life of the insulation board is limited, and the insulation board needs to be regularly replaced, thereby increasing maintenance cost of the device.

### SUMMARY

The present application provides an insulation board and a vacuum evaporation device assembly, which can solve the above problem, thereby improving an insulation effect, prolonging service life of the vacuum evaporation device and reducing maintenance cost of the device.

The present application provides an insulation board, which includes: a body; first bulges, disposed on the body and extending toward a first direction; and second bulges, disposed on the body and extending toward a second direction; and the first bulges and the second bulges are staggered, and the first direction is opposed to the second direction.

In an embodiment, shapes of the first bulges and the second bulges are cones, and bottoms of the cones are fixed to the body.

In an embodiment, the first bulges and the second bulges are hollow cones formed by stamping the body.

In an embodiment, vertex angles of the first bulges and the second bulges are respectively within a range from 25 degrees to 35 degrees.

In an embodiment, the body has a thickness of 0.3 mm to 0.7 mm.

In an embodiment, an interval between apexes of two adjacent ones of the first bugles is within a range of 20-25 times of the thickness of the body.

In an embodiment, an interval between an apex of one of the first bugles and a apex of one of the second bulges which is adjacent to the one of the first bugle is within a range of 10-13 times of the thickness of the body.

In an embodiment, a height of one of the first bulges and a height of one of the second bulges are respectively within a range of 1.15-1.5 times of the thickness of the body.

The present application further provides a vacuum evaporation device assembly, including: a process chamber; and any of the above insulation boards, one of the insulation board is disposed on an inner wall of the process chamber.

In an embodiment, wherein the insulation board includes a first insulation board and a second board adjacent to each other; wherein the first bulges and the second bulges of the first insulation board are staggered from the first bulges and the second bulges of the second insulation board.

In an embodiment, the further including a heater disposed in the process chamber; and the insulation board is disposed between the inner wall of the process chamber and the heater.

The emissivity of the insulation board provided by the present application is also decreased due to change of a surface shape, thereby blocking radiative heat transfer to a large extent. On the other hand, the apexes of the bulges are staggered, thereby reducing a projection angle of the surface, improving a heat transfer distance, playing a role of blocking the radiative heat transfer, improving the insulation effect of the insulation board, and prolonging the service life of the insulation board. Therefore, the insulation board is not frequently replaced, thereby reducing maintenance cost of the device.

### BRIEF DESCRIPTION OF DRAWINGS

FIG. 1 is a schematic diagram illustrating a section of an insulation board provided by an embodiment;

FIG. 2 is a structural schematic diagram illustrating a vacuum evaporation device assembly provided by an embodiment; and

FIG. 3 is a structural schematic diagram illustrating a vacuum evaporation device assembly provided by another embodiment.

### LIST OF REFERENCE NUMERALS

10—body
11—first bulge
12—second bulge
20—inner wall
0—heater

### DETAILED DESCRIPTION

Embodiments of the present application are described below in detail. Examples of embodiments are shown in drawings, wherein identical or similar numerals always indicate identical or similar elements or elements with identical or similar functions. Embodiments described below with reference to drawings are exemplary, and are only used for explaining the present application.

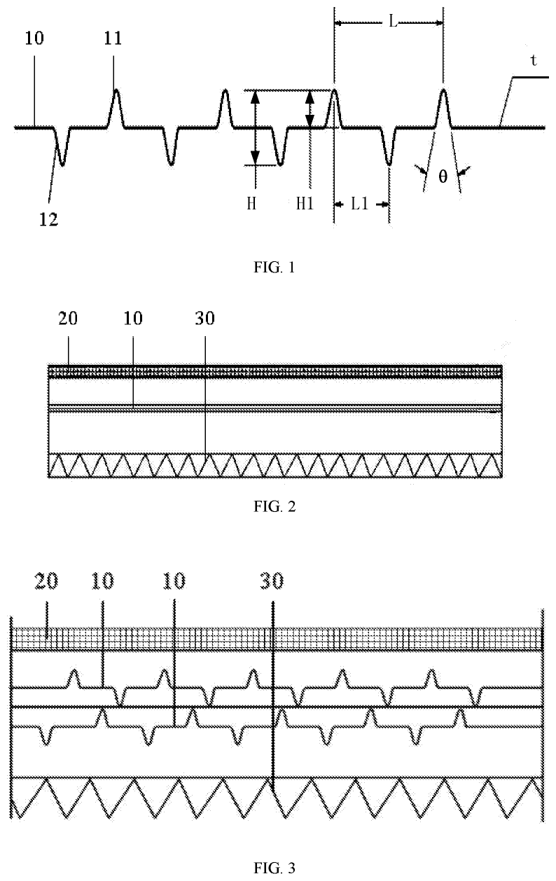

Referring to FIG. 1, an insulation board provided by the present embodiment includes a body 10, first bulges 11 extending toward a first direction and second bulges 12 extending toward a second direction are disposed on the body 10. The first bulges 11 and the second bulges 12 are staggered, and the first direction is opposed to the second direction.

The first bulges 11 and the second bulges 12 may be regularly distributed on the body 10 in a staggered manner, and may also be irregularly distributed on the body 10 in a staggered manner. Those skilled in the art may set according to an actual need. A regular distribution of the first bulges 11 and the second bulges 12 may reduce processing difficulty, and increase working efficiency.

The first bulges 11 and the second bulges 12 are respectively disposed at both sides of the body 10, and the emissivity of the insulation board is also decreased due to change of a surface shape of the body 10, thereby blocking radiative heat transfer at a large extent. On the other hand, apexes of the bulges are staggered, thereby reducing a projection angle of the surface, improving a heat transfer distance, playing a role of blocking the radiative heat transfer, improving the insulation effect of the insulation board, and prolonging the service life of the insulation board. Therefore, there is no need to frequently replace the insulation board, thereby reducing the maintenance cost of the device.

In an embodiment, shapes of the first bulges 11 and the second bulges 12 are cones, and bottoms of the cones are fixed to the body 10. In an embodiment, the first bulges 11 and the second bulges 12 are hollow cones formed by stamping the body, i.e., bottom circles of the cones have an open structure, and interiors of the cones have a hollow structure. Gas is filled in hollow parts of the hollow first bulges 11 and second bulges 12, and the insulation effect of the insulation board is better under the blocking of the gas.

Shapes of cross sections of the first bulges 11 and the second bulges 12 are isosceles triangles. A vertex angle of one of the isosceles triangles is a location in which one of the apexes of the first bulges 11 and the second bulges 12 is located. The first bulges 11 and the second bulges 12 may be arranged on the body 10 in an n*n matrix, wherein n is an integer greater than or equal to 2. The number of the first bulges 11 and the second bulges 12 may be determined based on an area of the body 10.

In an embodiment, the vertex angle of one of the first bulges 11 is within a range from 25 degrees to 35 degrees, and the vertex angle of one of the second bulges 12 is within a range from 25 degrees to 35 degrees. That is, the vertex angle of one of the isosceles triangles is within a range from 25 degrees to 35 degrees.

In an embodiment, an interval between the apexes of the adjacent ones of the first bugles 11 is L, which is 20-25 times of a thickness of the body 10. An interval between an apex of one of the first bugles 11 and a apex of one of the second bulges 12 which is adjacent to the one of the first bugles 11 is L1, which is 10-13 times of the thickness of the body 10. A height of one of the first bulges 11 is H1, and a height of one of the second bulges 12 also is H1, which may be 1.15-1.5 times of the thickness of the body 10, and a distance from the apex of the first bulge 11 to the apex of the second bulge 12 is 2*H1+t=H. The thickness of the body 10 is t, and the t may be within a range of 0.3 mm to 0.7 mm, such as 0.3 mm, 0.5 mm or 0.7 mm.

Through test certification, in the above parameter range, the insulation effect of the insulation board is excellent, and the service life is apparently prolonged.

The above insulation board may be formed by mold stamping, with steps including: the body 10 is placed in a mold cavity; one side of the body 10 is stamped to form the first bulges 11; the body 10 is turned over and placed in the mold cavity; and the other side of the body 10 is stamped to form the second bulges 12.

Referring to FIG. 2, and FIG. 3, the present embodiment further provides a vacuum evaporation device assembly, including a process chamber, and the insulation board provided by any embodiment is disposed on an inner wall 20 of the process chamber.

In an embodiment, referring to FIG. 2, one insulation board is blocked between the inner wall 20 of the process chamber and a heater 30, thereby isolating the heat and improving the insulation effect of the process chamber; and in the actual application process, it is found that the insulation board with such structure has a long service life, with no need to be frequently replaced, thereby reducing the maintenance cost of the device.

In an embodiment, referring to FIG. 3, the insulation board includes a first insulation board and a second board adjacent to each other. The first bulges 11 and the second bulges 12 of the first insulation board are staggered from the first bulges 11 and the second bulges 12 of the second insulation board. With such structure set, the insulation effect is improved, and the service life of the device assembly is prolonged.

In an embodiment, the insulation effect can be calculated according to a Stefan-Boltzmann formula:

φ=εAσT⁴;

where φ—thermal radiation energy; ε—object emissivity, i.e., emissivity; A—radiation surface area; σ—black-body radiation constant; and T—temperature of a workpiece for calculating the thermal radiation energy.

A radiant heat energy difference may be calculated with a formula: Δφ12=εAσ[(t1)⁴−(t2)⁴]. Through an actual data test, components of two layers of insulation boards may reduce the radiant heat loss by above 92%.

t1—heater temperature;
t2—temperature of the inner wall 20 of the process chamber.

What is claimed is:

1. An insulation board, comprising:
a body;
first bulges, disposed on the body and extending toward a first direction; and
second bulges, disposed on the body and extending toward a second direction;
wherein the first bulges and the second bulges are staggered, and the first direction is opposed to the second direction.

2. The insulation board according to claim 1, wherein shapes of the first bulges and the second bulges are cones, and bottoms of the cones are fixed to the body.

3. The insulation board according to claim 1, wherein the first bulges and the second bulges are hollow cones formed by stamping the body.

4. The insulation board according to claim 1, wherein vertex angles of the first bulges and the second bulges are respectively within a range from 25 degrees to 35 degrees.

5. The insulation board according to claim 1, wherein the body has a thickness of 0.3 mm to 0.7 mm.

6. The insulation board according to claim 5, wherein an interval between apexes of two adjacent ones of the first bugles is within a range of 20-25 times of the thickness of the body.

7. The insulation board according to claim 5, wherein an interval between an apex of one of the first bugles and a apex of one of the second bulges which is adjacent to the one of the first bugles is within a range of 10-13 times of the thickness of the body.

8. The insulation board according to claim 5, wherein a height of one of the first bulges and a height of one of the second bulges are respectively within a range of 1.15-1.5 times of the thickness of the body.

9. A vacuum evaporation device assembly, comprising:
a process chamber; and
an insulation board, wherein the insulation board is disposed on an inner wall of the process chamber, and the insulation board comprises:
a body;
first bulges, disposed on the body and extending toward a first direction; and
second bulges, disposed on the body and extending toward a second direction;
wherein the first bulges and the second bulges are staggered, and the first direction is opposed to the second direction.

10. The vacuum evaporation device assembly according to claim 9, wherein the insulation board comprises a first insulation board and a second board adjacent to each other; wherein the first bulges and the second bulges of the first insulation board are staggered from the first bulges and the second bulges of the second insulation board.

11. The vacuum evaporation device assembly according to claim 9, further comprising a heater disposed in the process chamber; and
wherein the insulation board is disposed between the inner wall of the process chamber and the heater.

12. The vacuum evaporation device assembly according to claim 9, wherein shapes of the first bulges and the second bulges are cones, and bottoms of the cones are fixed to the body.

13. The vacuum evaporation device assembly according to claim 9, wherein the first bulges and the second bulges are hollow cones formed by stamping the body.

14. The vacuum evaporation device assembly according to claim 9, wherein vertex angles of the first bulges and the second bulges are respectively within a range from 25 degrees to 35 degrees.

15. The vacuum evaporation device assembly according to claim 9, wherein the body has a thickness of 0.3 mm to 0.7 mm.

16. The vacuum evaporation device assembly according to claim 15, wherein an interval between apexes of two adjacent ones of the first bugles is within a range of 20-25 times of the thickness of the body.

17. The vacuum evaporation device assembly according to claim 15, wherein an interval between an apex of one of the first bugles and a apex of one of the second bulges which is adjacent to the one of the first bugles is within a range of 10-13 times of the thickness of the body.

18. The vacuum evaporation device assembly according to claim 15, wherein a height of one of the first bulges and a height of one of the second bulges are respectively within a range of 1.15-1.5 times of the thickness of the body.

19. The vacuum evaporation device assembly according to claim 10, further comprising a heater disposed in the process chamber; and
wherein the insulation board is disposed between the inner wall of the process chamber and the heater.

20. The insulation board according to claim 2, wherein the body has a thickness of 0.3 mm to 0.7 mm.
